(19) United States
(12) Patent Application Publication
(10) Pub. No.: US 2008/0203514 A1
(43) Pub. Date: Aug. 28, 2008

(54) High Performance CdxZn1-xTe X-Ray and Gamma Ray Radiation Detector and Method of Manufacture Thereof

(75) Inventor: Csaba Szeles, Allison Park, PA (US)

Correspondence Address: THE WEBB LAW FIRM, P.C., 700 KOPPERS BUILDING, 436 SEVENTH AVENUE, PITTSBURGH, PA, 15219, US

(73) Assignee: II-VI INCORPORATED, Saxonburg, PA (US)

(21) Appl. No.: 11/913,245

(22) PCT Filed: May 16, 2006
(86) PCT No.: PCT/US06/18779

§ 371 Date: Jan. 9, 2008

Related U.S. Application Data
(60) Provisional application No. 60/681,381, filed on May 16, 2005.

(51) Int. Cl. H01L 31/0296; H01L 31/18

(52) U.S. Cl. 257/442; 438/93; 257/E31.015; 257/E21.002

(57) ABSTRACT

The present invention is a radiation detector that includes a crystalline substrate formed of a II-VI compound and a first electrode covering a substantial portion of one surface of the substrate. A plurality of second, segmented electrodes is provided in spaced relation on a surface of the substrate opposite the first electrode. A passivation layer is disposed between the second electrodes on the surface of the substrate opposite the first electrode. The passivation layer can also be positioned between the substrate and one or both of the first electrode and each second electrode. The present invention is also a method of forming the radiation detector.

### BACKGROUND OF THE INVENTION

1. Field of the Invention

The present invention is a high performance room-temperature semiconductor x-ray and gamma ray radiation detector and method of manufacture thereof. Although the invention will be described in connection with a semi-insulating CdₓZn₁₋ₓTe (0≦x≦1) radiation detector, the invention is applicable to any II-VI compound with semi-insulating properties. As such, the invention is applicable to any nonlinear or electro-optical device or application where semi-insulating or high resistivity semiconductor material is required. The 0≦x≦1 concentration, or mole fraction range, encompasses CdZnTe with any Zn percentage including CdTe (x=1) and ZnTe (x=0).

2. Description of the Prior Art

With reference to FIG. 1, a typical, prior art radiation detector 1 includes a substrate 2 formed from a suitable II-VI compound, such as a CdZnTe crystal, a continuous electrode 4 covering one surface of substrate 2, a side electrode 6 forming an electrically conductive band around a side surface of substrate 2 and one or more segmented electrodes 8 on a surface of substrate 2 opposite continuous electrode 4. For purpose of describing the prior art and the present invention, radiation detector 1 and radiation detector 1′ (described herein) will be described as having a plurality of segment electrodes 8. However, this is not to be construed as limiting the invention since radiation detector 1 and/or radiation detector 1′ may include only a single electrode 8 if desired.

In use, detector 1 is typically bonded to a carrier or substrate 12 that includes a suitable pattern of conductors (not shown) that facilitate the acquisition of radiation event signals from segmented electrodes 8. More specifically, segmented electrodes 8 of detector 1 are bonded to electrode pads 14 of substrate 12, that match the geometry of segmented electrodes 8 of detector 1, via bonding bumps 16. Each bonding bump 16 can be, without limitation, an In bump, a low-temperature solder bump, a bump of conductive adhesive, and the like.

Segmented electrodes 8 can be pixels, strips, grids, steering grids, bars or rings of arbitrary size and geometry. Segmented electrodes 8 can be biased or unbiased relative to each other, to side electrode 6 and/or continuous electrode 4.

An exemplary embodiment of detector 1 includes 256 equal sized electrodes, like segmented electrodes 8, arranged in a 16×16 two-dimensional array that is surrounded by a side electrode, like side electrode 6, thereby defining a 257^{th} electrode.

Detector 1 is operated by applying one or more voltages between continuous electrode 4 and segmented electrodes 8 that cause charge carriers (electrons and holes) generated by radiation events in the volume of substrate 2 to drift toward continuous electrode 4 and segmented electrodes 8. Segmented electrodes 8 are coupled to appropriate readout circuitry via substrate 12 to convert the charge or current generated in each segmented electrode 8 from the motion of the generated charge carriers to an electronic signal tailored by the readout circuitry for further processing. Desirably, side electrode 6 is biased to optimize the electric field distribution in the volume substrate 2 and, as a result, optimize the performance of detector 1.

Problems encountered with prior art detector 1 include unacceptably low breakdown voltages between pairs of segmented electrodes 8 and/or between continuous electrode 4 and one or more segmented electrodes 8, with or without side electrode 6 present. Another problem with prior art detector 1 is that unacceptably high levels of leakage current may flow during operation thereby adversely effecting the performance of detector 1.

It would, therefore, be desirable to provide an improved detector that overcomes at least the above the problems and perhaps others.

### SUMMARY OF THE INVENTION

The present invention is a high performance room-temperature semiconductor x-ray and gamma ray radiation detector and method of manufacture thereof. The present invention provides a detector having excellent performance and long-term stability.

A detector in accordance with the present invention can include on a side surface thereof a passivation layer that exhibits very low side-surface leakage current, very high side surface breakdown voltage, excellent physical and chemical stability, and excellent long-term stability under continuous biasing conditions.

The detector can include between the segmented electrodes a passivation layer that exhibits very low surface leakage current, very high surface breakdown voltage, excellent physical and chemical stability, and excellent long-term stability under continuous biasing conditions.

The detector can include conductive electrodes. Also or alternatively, the detector can include insulator-conductor electrodes with superior current blocking properties that enable the detector to exhibit very low bulk leakage current, very high bulk breakdown voltage, excellent physical and chemical stability, and excellent long-term stability under continuous biasing conditions.

The detector can exhibit superior adhesion properties of the electrodes to the detector surface thereby eliminating electrode delamination due to surface contamination.

The detector can be formed with thin, highly electrically insulating layers.

The detector can be fabricated utilizing a unique combination of the following thin film deposition and surface modification techniques:
The combination ultraviolet light and ozone surface etching and oxidation;
Atomic hydrogen surface etching;
Pulsed DC reactive sputtering of insulating nitride (AlN, Si₃N₄ or similar) or oxide (Al₂O₃, SiO₂, TeO₂, CdO, CdTeO₃, ZnO or similar), oxynitride (AlON or similar) and selenide (ZnSe or similar) films;
Sputtering or evaporation of single layer or multi-layer metal electrodes including Pt, Au, In, Ti, Ni, Fe, Ta, Pd, Al, Ag, Cr, Mo, W, Zn, Te or any combination of them in binary, ternary and quaternary form; and
Photolithography to form segmented electrodes.

The detector includes a crystalline substrate formed of a II-VI compound and a first electrode covering a substantial portion of one surface of the substrate. A plurality of second, segmented electrodes is provided in spaced relation on a surface of the substrate opposite the first electrode. A passivation layer is disposed between the second electrodes on the surface of the substrate opposite the first electrode.

The passivation layer can be an oxide film having a thickness that enables a tunneling current to flow therethrough. The thickness of the passivation layer can be #250 Angstroms, desirably #100 Angstroms and more desirably #25 Angstroms. The passivation layer can also be disposed between the substrate and each second electrode.

The passivation layer can include a first insulating film formed of native oxides of the II-VI compound and a second insulating film overlaying the first film. The second insulating film can either be a nitride film, an oxynitride film or an oxide film.

The passivation layer can also cover at least part of a side surface of the substrate. A side electrode can be disposed on the passivation layer covering the at least part of the side surface of the substrate.

The passivation layer can also be disposed between the first electrode and the one surface of the substrate.

A method of forming the detector includes (a) forming a passivation layer on a crystalline substrate formed of a II-VI compound; (b) forming an array of apertures in the passivation layer on a first surface of the substrate; (c) depositing conductive material in each aperture and over the passivation layer on the first surface of the substrate; and (d) selectively removing the conductive material deposited over the passivation layer on the first surface of the substrate, whereupon the conductive material remains in each aperture of the passivation layer and the conductive material in each aperture of the passivation layer is separated from the conductive material in each other aperture of the passivation layer on the first surface of the substrate.

In the method, the conductive material deposited in each aperture can contact at least one of the first surface of the substrate and a thin oxide layer over the first surface of the substrate.

The method can further include removing at least part of the passivation layer from a second surface of the substrate opposite the first surface thereby exposing at least a portion of the second surface of the substrate and depositing conductive material on the exposed portion of the second surface of the substrate.

The method can further include depositing conductive material over the passivation layer on a side surface of the substrate.

The passivation layer can include a first insulating film formed of native oxides of the II-VI compound and a second insulating film overlaying the first film. Step (b) can include forming the array of apertures in the second film and step (c) can include depositing the conductive material on the exposed surface of the first film in each aperture.

At least a part of the second film can be removed from a second surface of the substrate opposite the first surface thereby exposing at least a portion of a surface of the first film on the second surface of the substrate. Conductive material can then be deposited on the exposed surface of the first film on the second surface of the substrate. Desirably, the first film has a thickness that enables a tunneling current to flow therethrough. The thickness of the first film can be #250 Angstroms, desirably #100 Angstroms and more desirably #25 Angstroms.

### BRIEF DESCRIPTION OF THE DRAWINGS

FIG. 1 is a cross-sectional view of a prior art radiation detector coupled to a substrate;

FIGS. 2-7 are cross-sectional views of a method of forming radiation detector in accordance with the present invention; and

FIG. 8 is a cross-section of another radiation detector in accordance with the present invention.

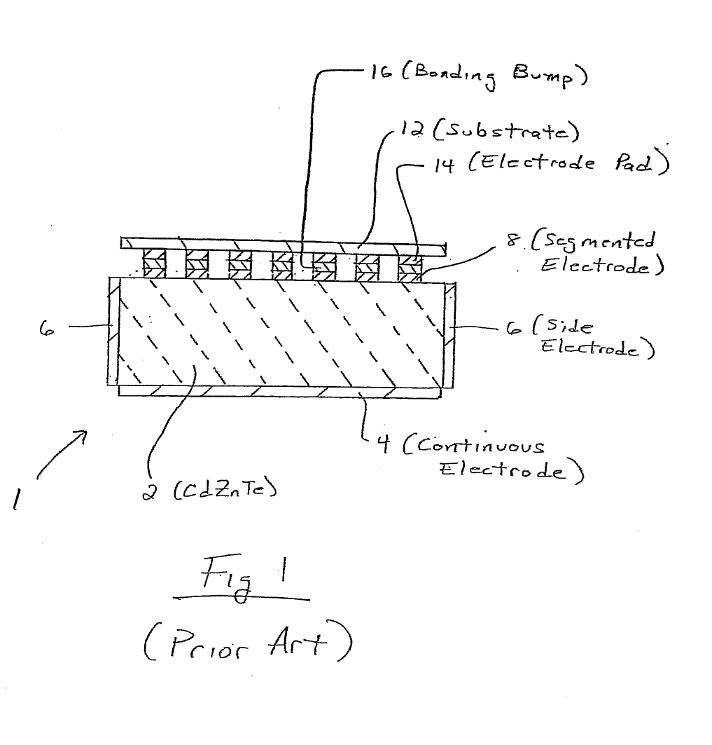

### DETAILED DESCRIPTION OF THE INVENTION

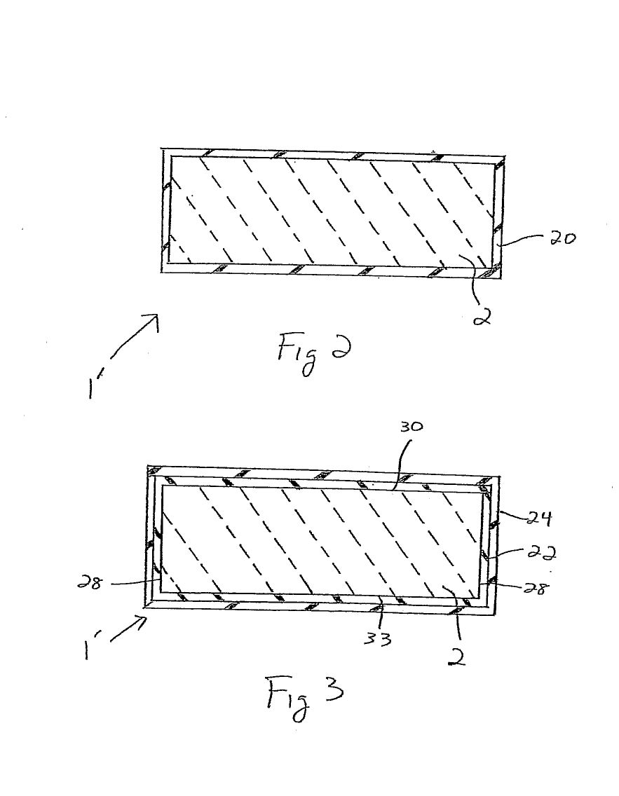

The present invention will be described with reference to FIGS. 2-7 where like reference numbers correspond to like elements.

With reference to FIG. 2, a method of forming a radiation detector 1′ in accordance with the present invention includes etching substrate 2, such as a substrate of CdZnTe, in a suitable manner to remove cutting, lapping and mechanical polishing damage from the surface(s) thereof. For the purpose of describing the present invention, hereinafter, it will be assumed that substrate 2 is made from CdZnTe. However, this is not to be construed as limiting the invention.

Substrate 2 can be etched utilizing any suitable wet or dry etching technique. Examples of suitable wet chemical etching solutions include a bromine methanol solution or a bromine ethanol solution. During etching of substrate 2, a thin, slightly oxidized amorphous Te film 20 typically forms on substrate 2.

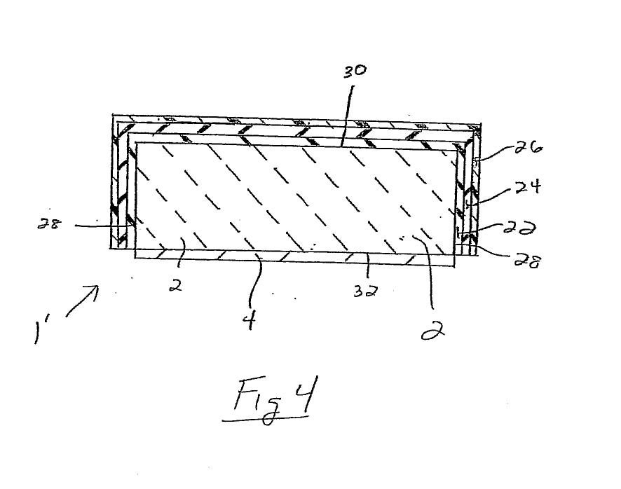

With reference to FIG. 3 and with continuing reference to FIG. 2, using a suitable technique, the oxidized Te film 20, if present, and any hydrocarbon contamination is removed from substrate 2. Thereafter, a thin oxide film 22 of native oxides of CdZnTe, such as Cd(Zn)TeOₓ, TeOₓ, CdO or ZnO, is formed on substrate 2 by UV/Ozone oxidation. This film 22 is highly insulating and provides low leakage current, high breakdown voltage and superior long term stability. However, film 22 is typically thin, e.g., #25 Angstroms, and, therefore, desirably needs further protection in the final embodiment of detector 1′.

An electrically insulating film 24 (500 to 5000 Angstrom), such as a nitride (AlN, Si₃N₄ or similar), oxynitride or oxide film, is deposited atop of film 22 to protect it from damage during further processing and during operation of detector 1′. Desirably, insulating film 24 is deposited by pulsed DC reactive sputtering under conditions to provide a highly electrically insulating, low-stress film.

Either one of film 22 and film 24 can be omitted from a top surface 30 of substrate 2 and/or around a side surface 28 of substrate 2 if the other film is deemed sufficient. For example, film 24 can be omitted on one or both of top surface 30 and around side surface 28 of substrate 2 whereupon film 22 is the sole insulating film. Alternatively, film 22 can be omitted on one or both of top surface 30 and around side surface 28 of substrate 2 whereupon film 24 is the sole insulating film. In yet another alternative, any combination of film 22 and/or film 24 can be utilized on top surface 30, side surface 28 and/or bottom surface 32 of substrate 2 as desired. For purpose of describing the present invention, films 22 and 24 will be described as being deposited on substrate 2. However, this is not to be construed as limiting the invention.

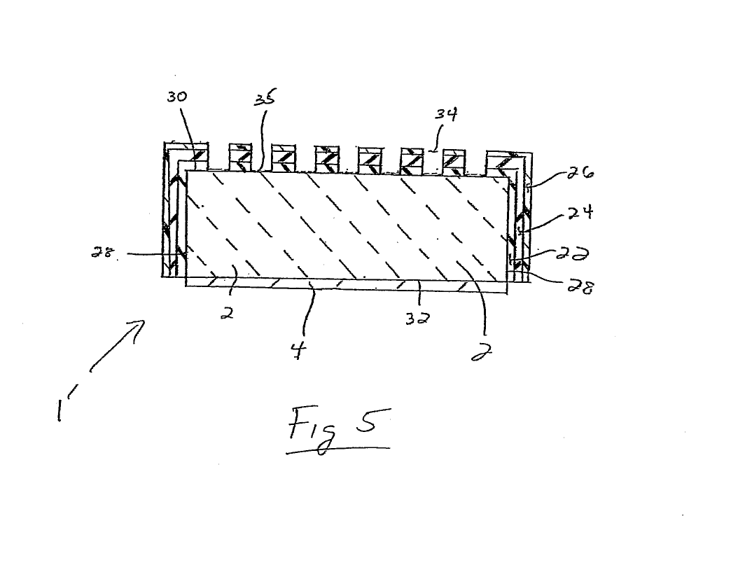

With reference to FIG. 4 and with continuing reference to FIG. 3, a protective film 26, such as a photoresist, is deposited atop the portion of insulating film 24 that resides on side surface 28 and top surface 30 of substrate 2. Thereafter, films 22 and 24 are removed (via chemo-mechanical polishing, wet or dry chemical etching, dry (ion or plasma) etching, or any other suitable and/or desirable etching technique) from bottom surface 32 of substrate 2 and continuous electrode 4 is deposited on bottom surface 32 by sputtering, evaporation or any other suitable and/or desirable deposition technique. If desired, prior to deposition of continuous electrode 4, bottom surface 32 may be cleaned via UV ozone oxidation either alone or followed by atomic hydrogen cleaning.

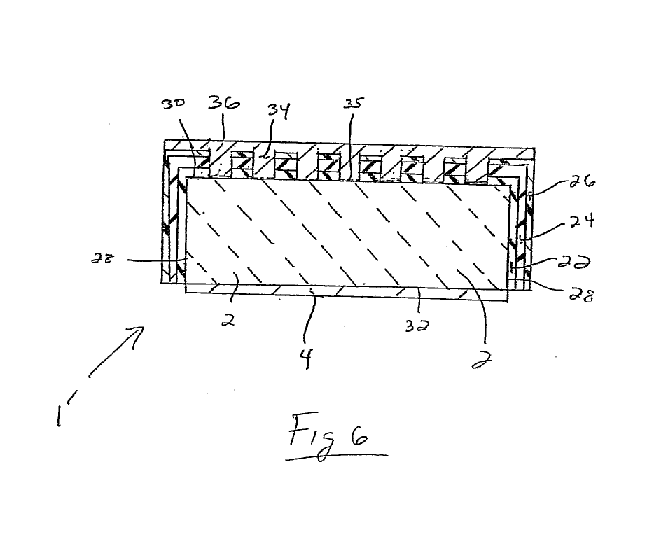

With reference to FIG. 5 and with continuing reference to FIG. 4, next, an array of apertures 34 is formed in protective film 26 residing atop top surface 30 of substrate 2 in a manner known in the art, such as by photolithographic chemical processing, and films 22 and 24 in alignment with each aperture 34 are removed by one or more suitable solvents. If protective film 26 is a photoresist, apertures 34 are formed therein by selectively etching soluble portions of the photoresist. A positive or negative photoresist can be used for this purpose.

Generally, a positive photoresist is one where each portion of the photoresist that is exposed to light, such as ultraviolet (UV) light, becomes soluble to a photoresist developer and the portion of the photoresist that is unexposed remains insoluble to the photoresist developer. A negative resist is one where each portion of the photoresist that is exposed to light becomes insoluble to the photoresist developer and the portion of the photoresist that is unexposed is soluble to the photoresist developer.

Next, UV/Ozone oxidation is applied to the top surface 30 of substrate 2 exposed in each aperture 34 to remove trace residues of photoresist therefrom. During UV/Ozone oxidation, a thin oxide layer 35 (shown in phantom) forms on the top surface 30 exposed in each aperture 34. If desired, thin oxide layer 35 can be removed utilizing any suitable etching technique, such as, without limitation, atomic hydrogen etching, desirably done in-situ in an electrode deposition chamber, such as a sputtering chamber, to avoid re-oxidation of the surface due to contact with ambient air.

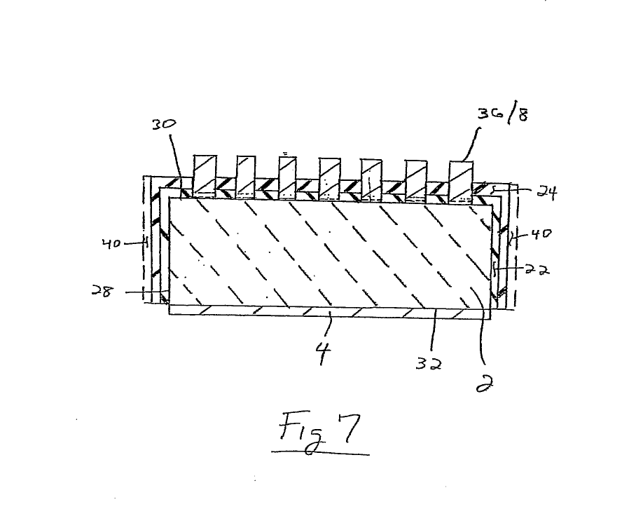

With reference to FIG. 6 and with continuing reference to FIG. 5, next a conductor 36, such as a conductive metal, is deposited atop the portion of protective film 26 overlaying top surface 30 and in each aperture 34 such that said conductor 36 contacts thin oxide layer 35 or, when thin oxide layer 35 is not present, the portion of the top surface 30 exposed in each aperture 34. Desirably, conductor 36 is deposited via sputtering or any other suitable vacuum deposition technique such as thermal evaporation or similar.

With reference to FIG. 7 and with continuing reference to FIG. 6, lastly, protective film 26, and any portion of conductor 36 thereon, is removed to form detector 1′ where each conductor 36 on thin oxide layer 35 or surface 30 defines a corresponding segmented electrode 8. Each segmented electrode 8 and/or continuous electrode 4 can be made of metal, metallic alloy or any suitable electrically conductive material or alloy. Each segmented electrode 8 and/or continuous electrode 4 can be a single conductor or a multi-layer stack of conductors.

Detector 1′ shown in FIG. 7 includes continuous electrode 4 on surface 32, segmented electrodes 8 on surface 30 (or thin oxide layer 35), film 22 and/or film 24 on surface 30 acting as a passivation layer between segmented electrodes 8, and film 22 and/or film 24 on side surface 28 of substrate 2, also acting as a passivation layer.

In an alternative configuration of detector 1′, a side electrode 40 (shown in phantom in FIG. 7) can be deposited atop the passivation layer on side surface 28 of substrate 2 to ensure that such electrode is electrically insulated from substrate 2. Side electrode 40 can be biased in any suitable manner relative to substrate 2 to adjust the electric field distribution in the volume of substrate 2 so that charge collection is optimized and optimum performance is achieved. The height and/or location of side electrode 40 on side surface 28 of substrate 2 can also be optimized to achieve the best possible detector performance.

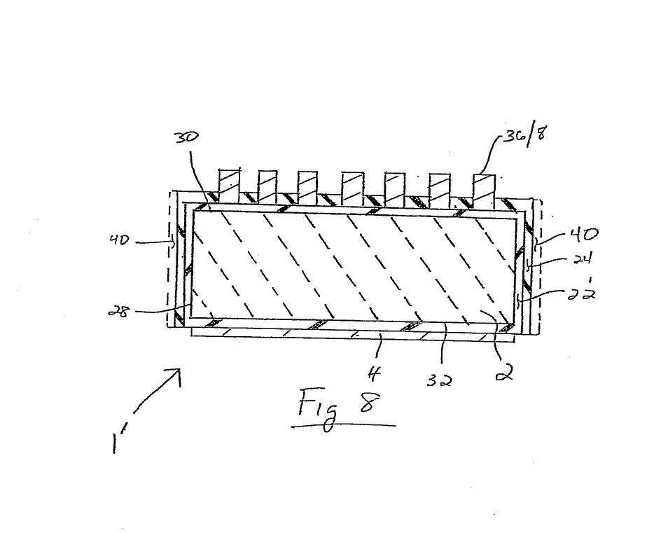

With reference to FIG. 8 and with continuing reference to FIGS. 2-7, in an alternate configuration of detector 1′, thin oxide film 22 can be retained on substrate 2. Thereafter, segmented electrodes 8 can be deposited atop the portion of film 22 overlaying top surface 30 of substrate 2 via apertures formed in film 24, if present. Desirably, each segmented electrode 8 is formed by depositing conductor 36 in each aperture 34 in protective film 26 in the manner discussed above in connection with FIG. 6. Thereafter, protective film 26, and any portion of conductor 36 thereon, is removed. The embodiment of detector 1′ with segment electrodes 8 deposited atop film 22 overlaying surface 30 of substrate 2 via apertures in film 24 is shown in FIG. 8. The embodiment of detector 1′ shown in FIG. 8 can also or alternatively include continuous electrode 4 deposited atop of the portion of film 22 overlaying bottom surface 32.

Provided film 22 is not too thick (e.g., #250 Angstroms, desirably #100 Angstroms, and more desirably #25 Angstroms) electrical current can flow between substrate 2 and continuous electrode 4 and/or between substrate 2 and each segmented electrode 8 by way of so-called tunneling current. If desired, the embodiment of detector 1′ shown in FIG. 8 can also include side detector 40 (shown in phantom) deposited atop the passivation layer on side surface 28 of substrate 2.

The present invention has been described with reference to the preferred embodiments. Obvious modifications and alterations will occur to others upon reading and understanding the preceding detailed description. For example, while the present invention has been described with reference to segmented electrodes on top surface 30 of substrate 2, it is envisioned that the foregoing technique can be adapted and modified as necessary in order to form segmented electrodes on top surface 30 and bottom surface 32 of substrate 2. It is intended that the invention be construed as including all such modifications and alterations insofar as they come within the scope of the appended claims or the equivalents thereof.

The invention claimed is:

1. A radiation detector comprising:
a crystalline substrate formed of a II-VI compound;
a first electrode covering a substantial portion of one surface of the substrate;
a plurality of second electrodes in spaced relation on a surface of the substrate opposite the first electrode; and
a passivation layer between the second electrodes on the surface of the substrate opposite the first electrode.

2. The radiation detector of claim 1, wherein the passivation layer is an oxide film having a thickness that enables a tunneling current to flow therethrough.

3. The radiation detector of claim 2, further including the passivation layer between the substrate and each second electrode.

4. The radiation detector of claim 1, wherein the passivation layer includes:
a first insulating film formed of native oxides of the II-VI compound; and
a second insulating film overlaying the first film.

5. The radiation detector of claim 4, wherein the second insulating film is one of a nitride film, an oxynitride film and an oxide film.

6. The radiation detector of claim 1, further including the passivation layer covering at least part of a side surface of the substrate.

7. The radiation detector of claim 6, further including a side electrode on the passivation layer covering the at least part of the side surface of the substrate.

8. The radiation detector of claim 1, further including the passivation layer between the first electrode and the one surface of the substrate.

9. A method of forming a radiation detector comprising:
(a) forming a passivation layer on a crystalline substrate formed of a II-VI compound;
(b) forming an array of apertures in the passivation layer on a first surface of the substrate;
(c) depositing conductive material in each aperture and over the passivation layer on the first surface of the substrate; and
(d) selectively removing the conductive material deposited over the passivation layer on the first surface of the substrate, whereupon the conductive material remains in each aperture of the passivation layer and the conductive material in each aperture of the passivation layer is separated from the conductive material in each other aperture of the passivation layer on the first surface of the substrate.

10. The method of claim 9, wherein the conductive material deposited in each aperture contacts at least one of the first surface of the substrate and a thin oxide layer over the first surface of the substrate.

11. The method of claim 9, further including:
removing at least part of the passivation layer from a second surface of the substrate opposite the first surface thereby exposing at least a portion of the second surface of the substrate; and
depositing conductive material on the exposed portion of the second surface of the substrate.

12. The method of claim 9, further including depositing conductive material over the passivation layer on a side surface of the substrate.

13. The method of claim 9, wherein:
the passivation layer includes a first insulating film formed of native oxides of the II-VI compound and a second insulating film overlaying the first film;
step (b) includes forming the array of apertures in the second film; and
step (c) includes depositing the conductive material on the exposed surface of the first film in each aperture.

14. The method of claim 13, further including:
removing at least a part of the second film from a second surface of the substrate opposite the first surface thereby exposing at least a portion of a surface of the first film on the second surface of the substrate; and
depositing conductive material on the exposed surface of the first film on the second surface of the substrate.

15. The method of claim 14, wherein the first film has a thickness #250 Angstroms, desirably #100 Angstroms and more desirably #25 Angstroms.

16. The method of claim 11, further including atomic hydrogen etching of the exposed portion of the second surface of the substrate prior to depositing the conductive material thereon.

17. The method of claim 9, further including atomic hydrogen etching of the exposed first surface of the substrate in each aperture of the passivation layer prior to step (c).
